(19) United States
(12) Patent Application Publication
(10) Pub. No.: US 2026/0063682 A1
(43) Pub. Date: Mar. 5, 2026

(54) Circuit Device And Electronic Apparatus

(71) Applicant: SEIKO EPSON CORPORATION, Tokyo (JP)

(72) Inventor: Shinichi SEKITA, Suwa (JP)

(21) Appl. No.: 19/312,753

(22) Filed: Aug. 28, 2025

(30) Foreign Application Priority Data
Aug. 29, 2024 (JP) 2024-147335

(51) Int. Cl. G01R 17/02; G01R 19/00; G01R 31/3835

(52) U.S. Cl. CPC G01R 17/02; G01R 19/0084; G01R 31/3835

(57) ABSTRACT

A circuit device includes a voltage divider circuit that divides and outputs a measurement target voltage to a voltage division node, a comparison circuit that compares a voltage of the voltage division node with a reference voltage, and a control circuit. The voltage divider circuit includes a first resistor to an n-th resistor provided in series between a measurement target voltage node and the voltage division node, and a first transistor to an n-th transistor with an i-th transistor coupled in parallel to an i-th resistor. The control circuit outputs measurement data by setting a j-th transistor to one of on and off, setting the first transistor to the (j−1)-th transistor to the other of on and off, and determining the j-th transistor is on or off based on a comparison result of the comparison circuit.

The present application is based on, and claims priority from JP Application Serial Number 2024-147335, filed Aug. 29, 2024, the disclosure of which is hereby incorporated by reference herein in its entirety.

### BACKGROUND

### 1. Technical Field

The present disclosure relates to a circuit device, an electronic apparatus, and the like.

### 2. Related Art

JP-A-2019-175755 discloses a measurement circuit that measures a battery voltage. The measurement circuit includes a counter, a resistance circuit that divides a battery voltage at a voltage division ratio set by a count value of the counter, and a comparator that compares an output voltage of the resistance circuit with a reference voltage. The resistance circuit includes seven resistors provided in series between a node of the battery voltage and an output node of the resistance circuit, and seven transistors each of which is coupled in parallel to each resistor. When the seven transistors are turned on or off according to the count value of the counter, the voltage division ratio of the resistance circuit changes. Concurrently, the battery voltage is measured based on a comparison result obtained by the comparator comparing the output voltage of the resistance circuit with the reference voltage.

JP-A-2019-175755 is an example of the related art.

When each transistor is switched between on and off, a source voltage or a drain voltage of the transistor fluctuates due to charge injection or the like. Due to the voltage fluctuation propagating to the input of the comparator, it is possible that the voltage is not accurately measured.

### SUMMARY

An aspect of the present disclosure relates to a circuit device including a voltage divider circuit that is provided between a measurement target voltage node and a ground node, divides and outputs a measurement target voltage that is a voltage of the measurement target voltage node to a voltage division node, a comparison circuit that compares a voltage of the voltage division node with a reference voltage, and a control circuit, wherein the voltage divider circuit includes a first resistor to an n-th resistor provided in series between the measurement target voltage node and the voltage division node, n being an integer of 3 or more, and a first transistor to an n-th transistor that are controlled to be turned on or off by control data from the control circuit with an i-th transistor coupled in parallel to an i-th resistor of the first resistor to the n-th resistor, i being an integer from 1 to n, the control circuit sets a j-th transistor to one of on and off and sets the first transistor to the (j−1)-th transistor to the other of on and off, determines the control data by determining on or off of the j-th transistor based on a comparison result of the comparison circuit, j being an integer from 2 to n, and outputs measurement data of the measurement target voltage based on the determined control data.

Another aspect of the present disclosure relates to an electronic apparatus including the circuit device described above and a battery, wherein the measurement target voltage is a battery voltage of the battery.

### BRIEF DESCRIPTION OF THE DRAWINGS

FIG. 1 shows a first configuration example of a circuit device.

FIG. 2 shows a configuration example of a circuit that generates control data in a control circuit.

FIG. 3 shows a waveform example illustrating an operation of the control circuit.

FIG. 4 shows a second configuration example of the circuit device.

FIG. 5 shows a third configuration example of the circuit device.

FIG. 6 is a truth table in a normal mode and a test mode.

FIG. 7 shows a detailed configuration example of a first trimming resistor and a second trimming resistor.

FIG. 8 shows a configuration example of an electronic apparatus and a system.

### DESCRIPTION OF EMBODIMENTS

A preferred embodiment of the present disclosure will be described in detail below. The present embodiment to be described does not unduly limit the description in What is claimed is and not all of the configurations described in the present embodiment are necessarily essential component elements. Note that coupling in the present embodiment includes electrical coupling. The electrical coupling is coupling in which an electrical signal, a voltage, or a current can be transmitted, and includes coupling in which information can be transmitted by an electrical signal. The electrical coupling may be coupling via a passive element or an active element.

### 1. First Configuration Example

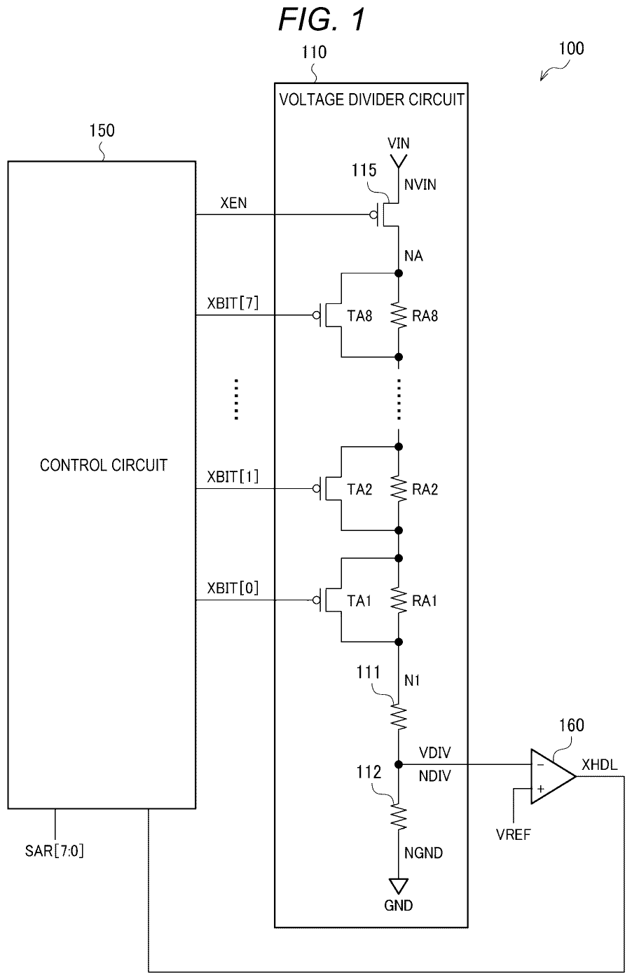

FIG. 1 shows a first configuration example of a circuit device 100. The circuit device 100 measures a voltage value of a measurement target voltage VIN and outputs measurement data SAR[7:0] as a result thereof. Here, the number of bits of the measurement data SAR[7:0] is 8, but the number of bits may be optional. The circuit device 100 includes a voltage divider circuit 110, a control circuit 150, and a comparison circuit 160. The circuit device 100 is, for example, an integrated circuit device in which a plurality of circuit elements are integrated on a semiconductor substrate.

The voltage divider circuit 110 is provided between a measurement target voltage node NVIN and a ground node NGND. That is, one end of the voltage divider circuit 110 is coupled to the measurement target voltage node NVIN, and the other end is coupled to the ground node NGND. The measurement target voltage node NVIN is a node to which the measurement target voltage VIN is input. The ground node NGND is a node to which a ground voltage GND is input. The voltage divider circuit 110 divides the measurement target voltage VIN and outputs the divided voltage to a voltage division node NDIV. The voltage divider circuit 110 includes a first resistor RA1 to an eighth resistor RA8, a first transistor TA1 to an eighth transistor TA8, a first resistance circuit 111, and a second resistance circuit 112. Further, the voltage divider circuit 110 may include a P-type MOS transistor 115.

The source of the P-type MOS transistor 115 is coupled to the measurement target voltage node NVIN, and the drain thereof is coupled to a node NA. An enable signal XEN is input from the control circuit 150 to the gate of the P-type MOS transistor 115.

The first resistor RA1 to the eighth resistor RA8 are coupled in series between the node NA and a first node N1. FIG. 1 illustrates an example in which the eighth resistor RA8, . . . , the second resistor RA2, and the first resistor RA1 are coupled in series in this order from the high potential side, but the coupling order is not limited thereto. Here, the number of resistors coupled in series is 8, but the number of resistors may be n. n is an integer of 3 or more. The resistance values of the first resistor RA1 to the eighth resistor RA8 are weighted in binary, and the resistance value of the eighth resistor RA8 is the maximum. That is, when j is an integer of from 2 to 8, the resistance value of RAj is twice the resistance value of RAj−1.

The first transistor to TA1 the eighth transistor TA8 are P-type MOS transistors. i is an integer from 1 to 8. The i-th transistor TAi is coupled in parallel to the i-th resistor RAi. That is, the source of the i-th transistor TAi is coupled to one end of the i-th resistor RAi, and the drain thereof is coupled to the other end of the i-th resistor RAi. A bit signal XBIT[i−1] of the control data XBIT[7:0] is input from the control circuit 150 to the gate of the i-th transistor TAi. The control data XBIT[7:0] is data for controlling the voltage division ratio of the voltage divider circuit 110.

The first resistance circuit 111 is provided between the first node N1 and the voltage division node NDIV. That is, one end of the first resistance circuit 111 is coupled to the first node N1, and the other end is coupled to the voltage division node NDIV. As an example, the resistance value of the first resistance circuit 111 is larger than the sum of the resistance values of the first resistor RA1 to the eighth resistor RA8. However, the present disclosure is not limited thereto, and the resistance value of the first resistance circuit 111 may be smaller than the sum of the resistance values of the first resistor RA1 to the eighth resistor RA8, or may be switchable according to the measurement range as will be described later.

The second resistance circuit 112 is provided between the voltage division node NDIV and the ground node NGND. That is, one end of the second resistance circuit 112 is coupled to the voltage division node NDIV, and the other end is coupled to the ground node NGND.

The comparison circuit 160 is a comparator that compares a voltage VDIV of the voltage division node NDIV with a reference voltage VREF. The reference voltage VREF is a constant voltage and may be input from a voltage generation circuit (not illustrated) provided in the circuit device 100 to the comparison circuit 160 or may be input from the outside of the circuit device 100. FIG. 1 illustrates an example in which the reference voltage VREF is input to the positive input terminal of the comparator and the voltage VDIV is input to the negative input terminal thereof. The comparison circuit 160 outputs an output signal XHDL as a comparison result. The output signal XHDL is at the low level when VDIV≥VREF, and at the high level when VDIV<VREF.

The control circuit 150 enables or disables the voltage divider circuit 110 based on the enable signal XEN. When the enable signal XEN is at the low level, the P-type MOS transistor 115 is on, and the voltage divider circuit 110 is enabled. When the enable signal XEN is at the high level, the P-type MOS transistor 115 is off, and the voltage divider circuit 110 is disabled. Hereinafter, it is assumed that the voltage divider circuit 110 is enabled.

The control circuit 150 changes the voltage division ratio of the voltage divider circuit 110 by changing the control data XBIT[7:0] to various values. The control circuit 150 determines the measurement data SAR[7:0] based on the logic level of the output signal XHDL output by the comparison circuit 160 for each value of the control data XBIT[7:0], and outputs the measurement data SAR[7:0].

Specifically, the voltage VDIV of the voltage division node NDIV is expressed by the following Expression (1). RA indicates a resistance value of a variable resistance circuit when the first resistor RA1 to the eighth resistor RA8 and the first transistor TA1 to the eighth transistor TA8 are regarded as the variable resistance circuit. R111 is a resistance value of the first resistance circuit 111, and R112 is a resistance value of the second resistance circuit 112.

$$VDIV = VIN * \{ R 112 / ( RA + R 111 + R 112 ) \} \qquad ( 1 )$$

The control circuit 150 changes the control data XBIT[7:0], and thus the resistance value changes and VDIV changes. In response thereto, the logic level of the output signal XHDL of the comparison circuit 160 is determined. The control circuit 150 determines the control data XBIT[7:0] when the voltage VDIV of the voltage division node NDIV is equal to the reference voltage VREF, and outputs logically inverted data BIT[7:0] as the measurement data SAR[7:0] of the measurement target voltage VIN. The logically inverted data BIT[7:0] is data obtained by logically inverting each bit of the control data XBIT[7:0].

As described above, no other resistor is provided between the measurement target voltage node NVIN and the first resistor RA1 to the eighth resistor RA8, and thus the on-resistances of the first transistor TA1 to the eighth transistor TA8 are smaller than those when another resistor is provided. Accordingly, the gate sizes of the first transistor TA1 to the eighth transistor TA8 can be reduced. As the gate size is reduced, the charge injection is reduced, and the possibility that the comparison circuit 160 makes an erroneous determination is reduced, thereby improving the accuracy of voltage measurement. As described above, the resistance value of the first resistance circuit 111 is larger than the total resistance value of the first resistor RA1 to the eighth resistor RA8, for example. Accordingly, the voltage fluctuation due to the charge injection of the first transistor TA1 to the eighth transistor TA8 is less likely to reach the voltage division node NDIV, and the possibility that the comparison circuit 160 makes an erroneous determination is reduced, thereby improving the accuracy of the voltage measurement.

An example of a method of determining the measurement data SAR[7:0] by the control circuit 150 is a binary search. The method will be described below. However, the method of determining the measurement data SAR[7:0] by the control circuit 150 is not limited to the binary search, but various algorithms may be adopted.

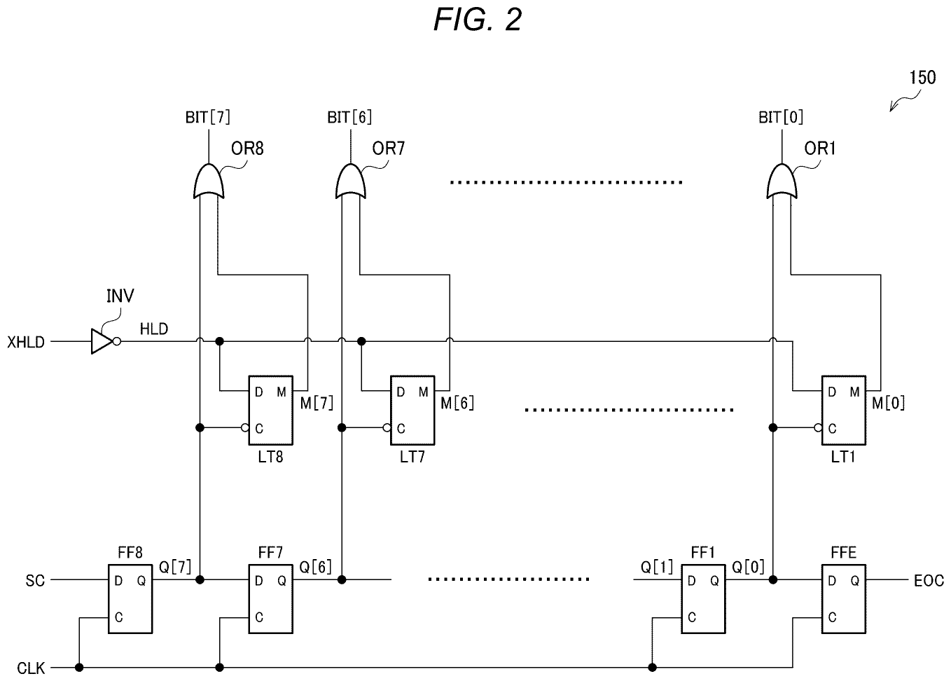

FIG. 2 shows a configuration example of a circuit that generates the data BIT[7:0] as the logically inverted data of the control data XBIT[7:0] in the control circuit 150. The control circuit 150 includes flip-flop circuits FF1 to FF8, a flip-flop circuit FFE, latch circuits LT1 to LT8, an inverter circuit INV, and logical sum circuits OR1 to OR8.

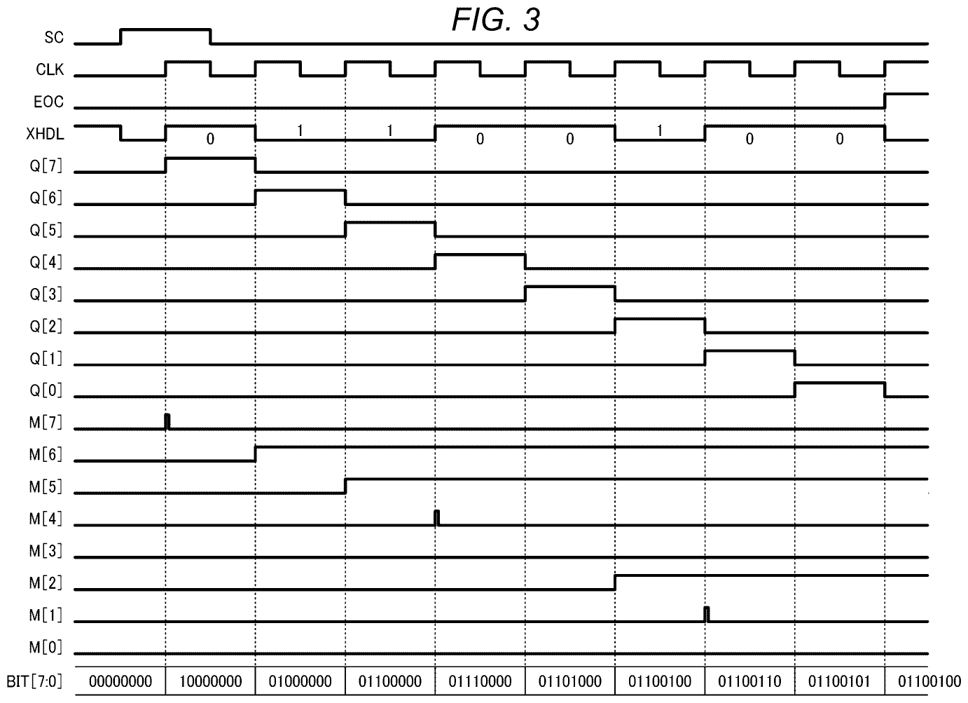

FIG. 3 shows a waveform example illustrating an operation of the control circuit 150 in FIG. 2. In this example, the measurement data SAR[7:0] is 01100100. The data is represented by binary. The waveform of the output signal XHDL of the comparison circuit 160 is denoted by 0 or 1 corresponding to the logic level of a signal HDL. The signal HDL is a logically inverted signal of the output signal XHDL.

At measurement, the control circuit 150 inputs a clock signal CLK from an oscillation circuit (not illustrated) or the like to clock terminals of the flip-flop circuits FF1 to FF8 and FFE. The flip-flop circuits FF1 to FF8 and FFE latch the input signals at the rising edge of the clock signal CLK. The period from the rising edge to the next rising edge of the clock signal CLK is referred to as one period of the clock signal, and the periods are sequentially referred to as a first period, a second period, . . . , and a ninth period.

The flip-flop circuits are coupled in series in the order of FF8, FF7, . . . , FF1, and FFE, and these constitute a shift register. When starting the measurement, the control circuit 150 inputs the high pulse of a signal SC to the data terminal of the flip-flop circuit FF8 at the head of the shift register. The signal SC changes from the low level to the high level before the first rising edge of the clock signal CLK, and changes from the high level to the low level at the first falling edge of the clock signal CLK. When the shift register sequentially shifts the signal SC, the output signal Q[7] of the flip-flop circuit FF8 is at the high level in the first period of the clock signal CLK, the output signal Q[6] of the flip-flop circuit FF7 is at the high level in the second period of the clock signal CLK, . . . , and the output signal Q[0] of the flip-flop circuit FF1 is at the high level in the eighth period of the clock signal CLK.

By the operation of the shift register, the output signal BIT[7] of the logical sum circuit OR8 is at the high level (“1”) in the first period of the clock signal CLK, the output signal BIT[6] of the logical sum circuit OR7 is at the high level in the second period of the clock signal CLK, . . . , and the output signal BIT[0] of the logical sum circuit OR1 is at the high level in the eighth period of the clock signal CLK. In this way, each bit of the measurement data SAR[7:0] is sequentially determined from the higher order by the output signal XHDL of the comparison circuit 160 when BIT[7], BIT[6], . . . , BIT[0] are sequentially set to the high level, and thus the binary search is performed.

Specifically, the inverter circuit INV outputs the logically inverted signal HDL of the output signal XHDL of the comparison circuit 160. The signal HDL is input to data terminals of the latch circuits LT1 to LT8. The logically inverted signal of the output signal Q[7] of the flip-flop circuit FF8 is input to the clock terminal of the latch circuit LT8. The latch circuit LT8 latches the signal HDL at the falling edge of Q[7]. Similarly, the latch circuit LT7 latches the signal HDL at the falling edge of Q[6], . . . , and the latch circuit LT1 latches the signal HDL at the falling edge of Q[0]. Taking the first period and the second period as an example, the output signal BIT[7] is at the high level in the first period and at the low level at the start of the second period. Therefore, the latch circuit LT8 latches the signal HDL at the start of the second period. The latched signal HDL is the logically inverted signal of the output signal XHDL of the comparison circuit 160 corresponding to the output signal BIT[7] at the high level, and is at the low level (“0”) in the example in FIG. 3. Since the output signal M[7] of the latch circuit LT8 is at the low level, the output signal BIT[7] of the logical sum circuit OR8 is determined to be at the low level (“0”) at the start of the second period. Subsequently, at the starts of the third to ninth periods, the logic levels of the output signals BIT[6] to BIT[0] of the logical sum circuits OR7 to OR1 are sequentially determined. The control circuit 150 outputs the determined data BIT[7:0] as the measurement data SAR[7:0].

The last flip-flop circuit FFE of the shift register outputs an end signal EOC at the high level in the ninth period. When the end signal EOC is at the high level, the control circuit 150 outputs the data BIT[7:0] determined as described above as the measurement data SAR[7:0].

In the binary search, since the number of transistors that are switched on and off is smaller than that in a counter method as disclosed in JP-A-2019-175755 or the like, the voltage fluctuation due to charge injection can be reduced. In the counter method as disclosed in JP-A-2019-175755, for example, the data BIT[7:0] may be switched from 01111111 to 10000000, and the eight transistors may be simultaneously switched on and off. On the other hand, according to the present embodiment, as shown in FIG. 3, the number of transistors that are simultaneously switched on and off is two at the maximum. For example, in the second period and the third period, the data BIT[7:0] is switched from 10000000 to 01000000, and only the two transistors are simultaneously switched on and off. When two transistors are simultaneously switched, the two transistors are adjacent to each other. When one of the two transistors is switched from on to off and the other is switched from off to on, the charge injections can be partially canceled out. For example, the source-side charge injection of one transistor and the drain-side charge injection of the other transistor are cancelled out each other. Accordingly, the influence of the charge injection can be reduced.

In the present embodiment, the circuit device 100 includes the voltage divider circuit 110, the comparison circuit 160, and the control circuit 150. The voltage divider circuit 110 is provided between the measurement target voltage node NVIN and the ground node NGND, divides the measurement target voltage VIN, which is the voltage of the measurement target voltage node NVIN, and outputs the divided voltage to the voltage division node NDIV. The comparison circuit 160 compares the voltage VDIV of the voltage division node NDIV with the reference voltage VREF. The voltage divider circuit 110 includes the first resistor RA1 to the n-th resistor RAn and the first transistor TA1 to the n-th transistor TAn. n is an integer of 3 or more. The first resistor RA1 to the n-th resistor RAn are provided in series between the measurement target voltage node NVIN and the voltage division node NDIV. The i-th transistor TAi of the first transistor TA1 to the n-th transistor TAn is coupled in parallel to the i-th resistor RAi of the first resistor RA1 to the n-th resistor RAn. i is an integer from 1 to n. The first transistor TA1 to the n-th transistor TAn are controlled to be turned on or off by the control data XBIT[n−1:0] from the control circuit 150. The control circuit 150 sets the j-th transistor TAj to one of on and off, and sets the first transistor TA1 to the (j−1)-th transistor TAj−1 to the other of on and off. The j is an integer from 2 to n. The control circuit 150 determines the control data XBIT[7:0] by determining whether the j-th transistor Taj is on or off based on the comparison result of the comparison circuit 160. The control circuit 150 outputs the measurement data SAR[7:0] of the measurement target voltage VIN based on the determined control data XBIT[7:0].

According to the present embodiment, the first transistor TA1 to the n-th transistor TAn are turned on one by one, and the bit of the measurement data SAR[7:0] corresponding to the turned-on transistor is determined according to the comparison result of the comparison circuit 160 for each transistor. Accordingly, the number of transistors that are simultaneously switched on and off in the voltage measurement can be reduced, and the voltage fluctuation due to charge injection from the transistors can be reduced. Thus, the accuracy of the voltage measurement can be improved.

In the example in FIG. 1, n=8. In the examples in FIGS. 2 and 3, the data BIT[7:0] as the logically inverted data of the control data XBIT[7:0] is determined and the measurement data SAR[7:0] of the measurement target voltage VIN is output based on the data BIT[7:0], which is equivalent to determining the control data XBIT[7:0] and outputting the measurement data SAR[7:0] of the measurement target voltage VIN based on the control data XBIT[7:0]. In the examples in FIGS. 2 and 3, the control circuit 150 sets the j-th transistor TAj to on, sets the first transistor TA1 to the (j−1)-th transistor TAj−1 to off, and determines whether the j-th transistor TAj is on or off based on the comparison result of the comparison circuit 160. However, the control circuit 150 may set the j-th transistor TAj to off, set the first transistor TA1 to the (j−1)-th transistor TAj−1 to on, and determine whether the j-th transistor TAj is on or off based on the comparison result of the comparison circuit 160.

In the present embodiment, the control circuit 150 may set the n-th transistor TAn to one of on and off, set the first transistor TA1 to the (n−1)-th transistor TAn−1 to the other of on and off, and determine whether the n-th transistor TAn is on or off based on the comparison result of the comparison circuit 160. The control circuit 150 may set the (n−1)-th transistor TAn−1 to one of on and off, set the first transistor TA1 to the (n−2)-th transistor TAn−2 to the other of on and off, and determine on or off of the (n−1)-th transistor TAn−1 based on the comparison result of the comparison circuit 160. Subsequently, in the same manner, the control circuit 150 may set the first transistor TA1 to on or off and determine on or off of the first transistor TA1 based on the comparison result of the comparison circuit 160.

In this way, as described above with reference to FIGS. 2 and 3, the maximum number of transistors that are simultaneously switched on and off is two. Accordingly, the number of transistors that are simultaneously switched on and off in the voltage measurement can be reduced and the voltage fluctuation due to charge injection from the transistors can be reduced as compared with the counter method as disclosed in JP-A-2019-175755 or the like.

In the present embodiment, in the first resistor RA1 to the n-th resistor RAn, the resistance value of the first resistor RA1 is the minimum, the resistance value of the n-th resistor RAn is the maximum, and the resistance values are weighted in binary.

According to the present embodiment, the resistance value of a variable resistance circuit including the first resistor RA1 to the n-th resistor RAn and the first transistor TA1 to the n-th transistor TAn is linear with respect to the data BIT[7:0]. While the first transistor TA1 to the n-th transistor TAn are sequentially turned on as described above, the measurement data SAR[7:0] is determined bit by bit from the higher order based on the comparison result of the comparison circuit 160. That is, the measurement data SAR[7:0] is determined by the so-called binary search.

In the present embodiment, the voltage divider circuit 110 may include the first resistance circuit 111 provided between the first node N1 and the voltage division node NDIV. The first resistor RA1 to the n-th resistor RAn may be coupled in series between the first node N1 and the measurement target voltage node NVIN.

In the present embodiment, the resistance value of the first resistance circuit 111 may be larger than the total resistance value of the first resistor RA1 to the n-th resistor RAn.

According to the present embodiment, the voltage fluctuation caused due to charge injection of the first transistor TA1 to the n-th transistor TAn is attenuated by the first resistance circuit 111 and propagates to the voltage division node NDIV. Accordingly, the comparison by the comparison circuit 160 is less likely to be affected by the voltage fluctuation, and the accuracy of the voltage measurement is improved.

In the present embodiment, the voltage divider circuit 110 may include the second resistance circuit 112 provided between the voltage division node NDIV and the ground node NGND.

According to the present embodiment, the voltage divider circuit 110 can divide the voltage between the measurement target voltage VIN and the ground voltage GND by the first resistor RA1 to the n-th resistor RAn, the first resistance circuit 111, and the second resistance circuit 112.

In the present embodiment, the circuit device 100 may intermittently measure the measurement target voltage VIN. The term “intermittently measure” means that, with obtaining the measurement data SAR[7:0] at one or more times as one measurement operation, there is a period in which the measurement target voltage VIN is not measured, that is, the measurement data SAR[7:0] is not obtained between the measurement operations.

According to the present embodiment, the power consumption by the measurement is intermittent, and thus the power consumption of the circuit device 100 can be reduced. The measurement time can be shortened by the binary search as compared with the counter method as disclosed in JP-A-2019-175755, and thus the operation time of the circuit can be shortened, and the power consumption can be further reduced.

### 2. Second Configuration Example

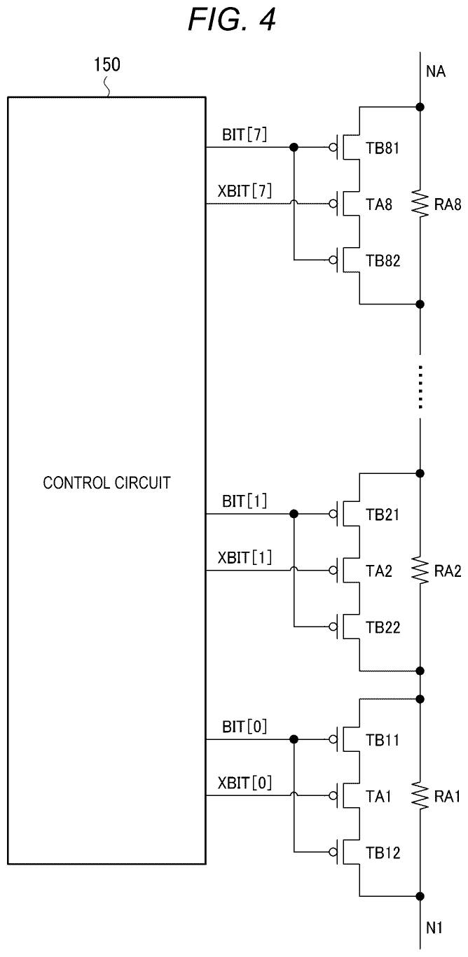

FIG. 4 shows a second configuration example of the circuit device 100. The configurations other than the configurations illustrated and described in FIG. 4 are the same as those of the first configuration example. In the second configuration example, the voltage divider circuit 110 further includes a first charge absorption transistor TBi1 and a second charge absorption transistor TBi2. i is an integer from 1 to 8.

The first charge absorption transistor TBi1 and the second charge absorption transistor TBi2 are P-type MOS transistors. The source and the drain of the first charge absorption transistor TBi1 are coupled to the source of the i-th transistor TAi. The source and the drain of the second charge absorption transistor TBi2 are coupled to the drain of the i-th transistor TAi. The logically inverted signal BIT[i−1] of the signal XBIT[i−1] input to the gate of the i-th transistor TAi is input to the gates of the first charge absorption transistor TBi1 and the second charge absorption transistor TBi2. The gate area of the first charge absorption transistor TBi1 and the second charge absorption transistor TBi2 is half the gate area of the i-th transistor TAi.

i=1 is taken as an example. When the signal XBIT[0] changes from the low level to the high level or from the high level to the low level, charge is generated in the source and the drain of the first transistor TA1 by charge injection. However, since the logic level of the signal BIT[0] changes by converse logic to the signal XBIT[0], the first charge absorption transistor TB11 absorbs the charge of the source, and the second charge absorption transistor TB12 absorbs the charge of the drain. Accordingly, the voltage fluctuation of the voltage division node NDIV due to the charge injection is reduced. Since the gate area of each charge absorption transistor is half the gate area of the first transistor TA1, the amount of charge generated by charge injection and the amount of charge absorbed by the two charge absorption transistors are the same. Accordingly, the voltage fluctuation of the voltage division node NDIV due to the charge injection is effectively reduced. The same applies to the case of i=2 to 8.

In the present embodiment, the voltage divider circuit 110 includes the first charge absorption transistor TBi1 and the second charge absorption transistor TBi2. The first charge absorption transistor TBi1 is coupled to the source of the i-th transistor TAi, and the inverted signal BIT[i−1] of the i-th bit XBIT[i−1] of the control data XBIT[7:0] is input to the gate. The second charge absorption transistor TBi2 is coupled to the drain of the i-th transistor TAi, and the inverted signal BIT[i−1] of the i-th bit XBIT[i−1] is input to the gate thereof.

As described above, each charge absorption transistor absorbs the charge of the source and the drain of the i-th transistor TAi by charge injection. Accordingly, the voltage fluctuation of the voltage division node NDIV due to the charge injection is reduced.

In the present embodiment, the gate area of the first charge absorption transistor TBi1 and the second charge absorption transistor TBi2 may be half the gate area of the i-th transistor TAi.

As described above, the amount of charge generated by the charge injection and the amount of charge absorbed by the two charge absorption transistors are the same. Accordingly, the voltage fluctuation of the voltage division node NDIV due to the charge injection is effectively reduced.

### 3. Third Configuration Example

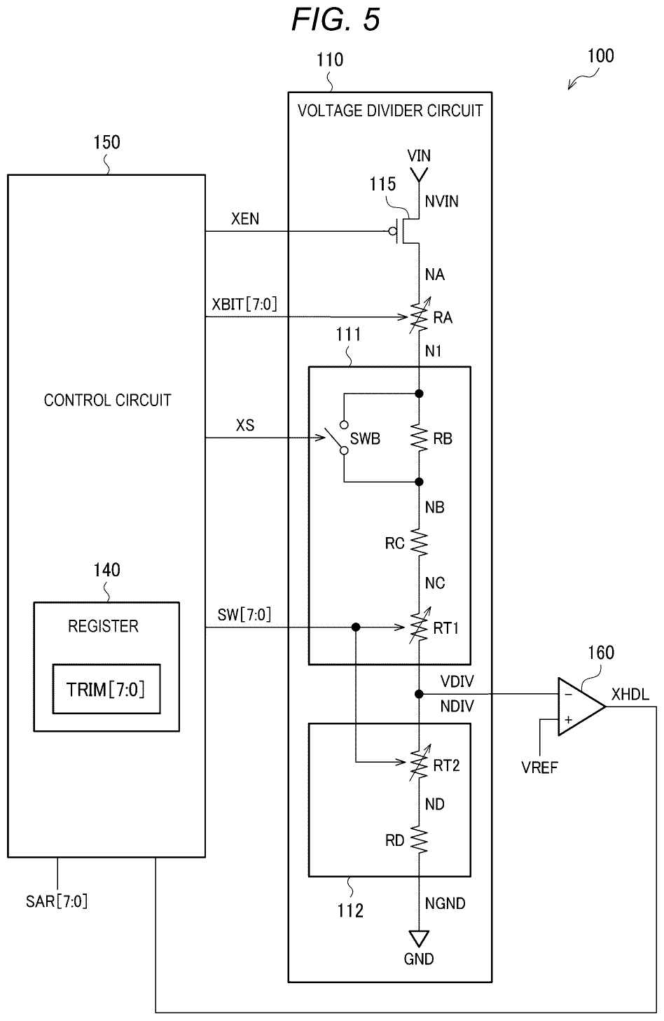

FIG. 5 shows a third configuration example of the circuit device 100. The configurations other than the configurations described below are the same as those of the first configuration example or the second configuration example. In the third configuration example, the voltage divider circuit 110 includes the P-type MOS transistor 115, a variable resistance circuit RA, the first resistance circuit 111, and the second resistance circuit 112. The variable resistance circuit RA refers to a variable resistance circuit including the first to eighth resistors RA1 to RA8 and the first to eighth transistors TA1 to TA8. The control circuit 150 includes a register 140.

The first resistance circuit 111 includes a resistor RB, a switch SWB, a resistor RC, and a first trimming resistor RT1. The resistor RB and the switch SWB are coupled in parallel between the first node N1 and a node NB. The resistor RC is coupled between the node NB and a node NC. The first trimming resistor RT1 is coupled between the node NC and the voltage division node NDIV.

The second resistance circuit 112 includes a second trimming resistor RT2 and a resistor RC. The second trimming resistor RT2 is coupled between the voltage division node NDIV and a node ND. The resistor RC is coupled between the node NC and the ground node NGND.

The control circuit 150 controls the switch SWB to be turned on or off by outputting a switch control signal XS to the switch SWB, and sets a measurement range of the measurement target voltage VIN. The measurement range is a range between the voltage value of the measurement target voltage VIN corresponding to the minimum value of the measurement data SAR[7:0] and the voltage value of the measurement target voltage VIN corresponding to the maximum value of the measurement data SAR[7:0]. The measurement range when the switch SWB is on is lower than the measurement range when the switch SWB is off. That is, the upper limit of the measurement range when the switch SWB is on is lower than the upper limit of the measurement range when the switch SWB is off, and the lower limit of the measurement range when the switch SWB is on is lower than the lower limit of the measurement range when the switch SWB is off.

The first trimming resistor RT1 and the second trimming resistor RT2 are variable resistors, and adjust voltage measurement variations due to variations of the reference voltage VREF. For example, the reference voltage VREF is generated based on the bandgap voltage, and the reference voltage VREF varies due to individual variations in the bandgap voltage. In this case, the resistance ratio between the first trimming resistor RT1 and the second trimming resistor RT2 is adjusted SO that the same measurement data SAR[7:0] is obtained for the same measurement target voltage VIN. Specifically, the register 140 stores trimming data TRIM[7:0]. The control circuit 150 outputs the trimming data TRIM[7:0] to the first trimming resistor RT1 and the second trimming resistor RT2 as resistance ratio control data SW[7:0]. Thus, the resistance ratio between the first trimming resistor RT1 and the second trimming resistor RT2 is set. The trimming data TRIM[7:0] is measured in advance at the time of manufacturing the circuit device 100 or the like. For example, the circuit device 100 includes a nonvolatile memory (not illustrated) that stores the trimming data TRIM[7:0] in advance, and the control circuit 150 loads the trimming data TRIM[7:0] from the nonvolatile memory to the register 140. Alternatively, an electronic apparatus including the circuit device 100 may include a nonvolatile memory (not illustrated) that stores the trimming data TRIM[7:0] in advance and a processing device. The trimming data TRIM[7:0] may be written from the nonvolatile memory into the register 140 by the processing device.

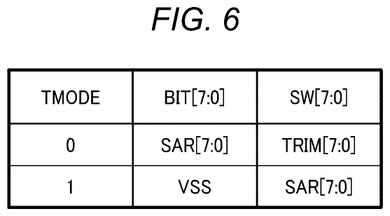

A method of determining the trimming data TRIM[7:0] will be described. FIG. 6 is a truth table in a normal mode and a test mode. In the normal mode, a mode signal TMODE is set to 0. The normal mode is a mode in which the circuit device 100 performs a normal operation such as voltage measurement. In the test mode, the mode signal TMODE is set to 1. The test mode is a mode for determining the trimming data TRIM[7:0]. The mode signal TMODE is set by register from, for example, an external device. TMODE=0 may be a default setting, or may be a register setting from a processing device of an electronic apparatus including the circuit device 100. TMODE=1 is set by register from, for example, an inspection apparatus that inspects the circuit device 100.

When TMODE=1, that is, in the test mode, the control circuit 150 outputs 00000000 as the data BIT[7:0], that is, outputs 11111111 as the control data XBIT[7:0]. Accordingly, the first transistor TA1 to the eighth transistor TA8 are all turned off, and the resistance value of the variable resistance circuit RA is maximized. The control circuit 150 changes the resistance ratio control data SW[7:0] to change the resistance ratio between the first trimming resistor RT1 and the second trimming resistor RT2. For example, the control circuit 150 sequentially changes the resistance ratio from the minimum value to the maximum value, and outputs the resistance ratio control data SW[7:0] when the output signal XHDL of the comparison circuit 160 is inverted as the measurement data SAR[7:0]. The measurement data SAR[7:0] is the trimming data TRIM[7:0] in the normal mode. For example, an external inspection apparatus acquires the measurement data SAR[7:0] from the circuit device 100 in the test mode, and writes the measurement data SAR[7:0] as the trimming data TRIM[7:0] in a nonvolatile memory (not illustrated) or the like.

When TMODE=0, that is, in the normal mode, the trimming data TRIM[7:0] written in the nonvolatile memory or the like is loaded into the register 140. The control circuit 150 outputs the trimming data TRIM[7:0] of the register 140 as the resistance ratio control data SW[7:0]. Thus, the resistance ratio between the first trimming resistor RT1 and the second trimming resistor RT2 is controlled by the trimming data TRIM[7:0] determined in the test mode. The control circuit 150 determines the data BIT[7:0] corresponding to the measurement target voltage VIN by the method described in the first configuration example, and outputs the data BIT[7:0] as the measurement data SAR[7:0].

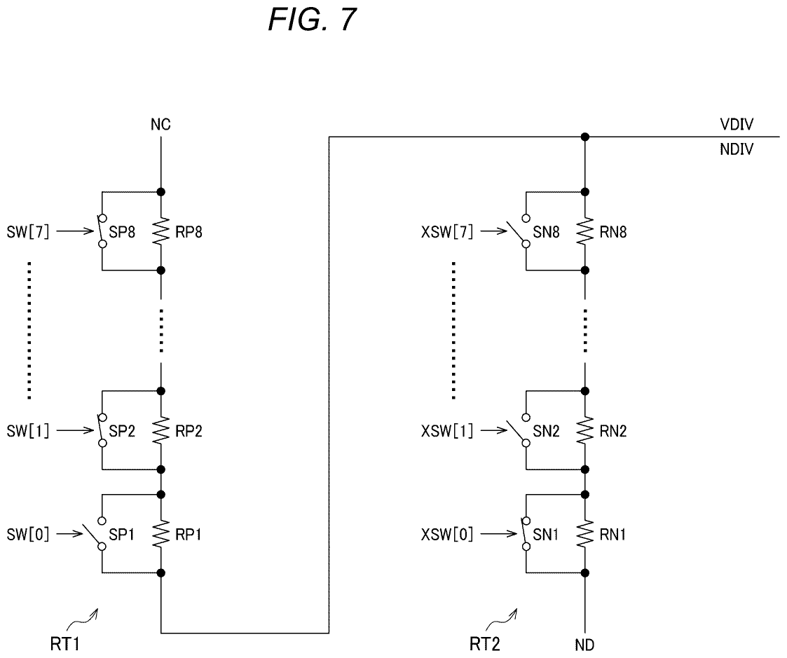

FIG. 7 shows a detailed configuration example of the first trimming resistor RT1 and the second trimming resistor RT2. The first trimming resistor RT1 includes resistors RP1 to RP8 and switches SP1 to SP8. The resistors RP1 to RP8 are coupled in series between the node NC and the voltage division node NDIV. The switch SPk is coupled in parallel to the resistor RPk. The k is an integer from 1 to 8. The resistance values of the resistors RP1 to RP8 are weighted in binary. The second trimming resistor RT2 includes resistors RN1 to RN8 and switches SN1 to SN8. The resistors RN1 to RN8 are coupled in series between the voltage division node NDIV and the node ND. The switch SNk is coupled in parallel to the resistor RNk. The resistance values of the resistors RN1 to RN8 are weighted in binary. The resistance value of the resistor RNk is the same as the resistance value of the resistor RPk.

A bit signal SW[k−1] of the resistance ratio control data SW[7:0] is input from the control circuit 150 to the switch SPk of the first trimming resistor RT1. The switch SPk is on when SW[k−1] is at the high level, and is off when SW[k−1] is at the low level. A logically inverted signal XSW[k−1] of the bit signal SW[k−1] is input to the switch SNk of the second trimming resistor RT2. The switch SNk is on when XSW[k−1] is at the high level, and is off when XSW[k−1] is at the low level. When one of the switch SPk of the first trimming resistor RT1 and the switch SNk of the second trimming resistor RT2 is on, the other is off, and the resistance values of the resistor RPk and the resistor RNk are the same. Therefore, the sum of the resistance values of the first trimming resistor RT1 and the second trimming resistor RT2 does not change as RP1+RP2+ . . . +RP8, and the resistance ratio between the first trimming resistor RT1 and the second trimming resistor RT2 changes.

In the present embodiment, the voltage divider circuit 110 includes the first trimming resistor RT1 provided between the first node N1 and the voltage division node NDIV, and the second trimming resistor RT2 provided between the voltage division node NDIV and the ground node NGND. The first resistor RA1 to the n-th resistor RAn are coupled in series between the measurement target voltage node NVIN and the first node N1. The variations of the reference voltage VREF are adjusted by the resistance ratio between the first trimming resistor RT1 and the second trimming resistor RT2.

According to the present embodiment, the variations of the voltage measurement result due to the variations of the reference voltage VREF are adjusted. For example, even when the reference voltage VREF varies due to individual variations of the circuit device 100, the same measurement data SAR[7:0] is obtained for the same measurement target voltage VIN in each individual.

In the present embodiment, the total resistance value of the first trimming resistor RT1 and the second trimming resistor RT2 may be constant regardless of the resistance ratio.

When the total resistance value of the voltage divider circuit 110 changes due to the variation adjustment of the reference voltage VREF, the measurement range of the measurement target voltage VIN may fluctuate. According to the present embodiment, since the total resistance value of the first trimming resistor RT1 and the second trimming resistor RT2 does not change, the total resistance value of the voltage divider circuit 110 does not change even when the variations of the reference voltage VREF are adjusted. Accordingly, the measurement range of the measurement target voltage VIN does not fluctuate even when the variations of the reference voltage VREF are adjusted.

### 4. Electronic Apparatus and System

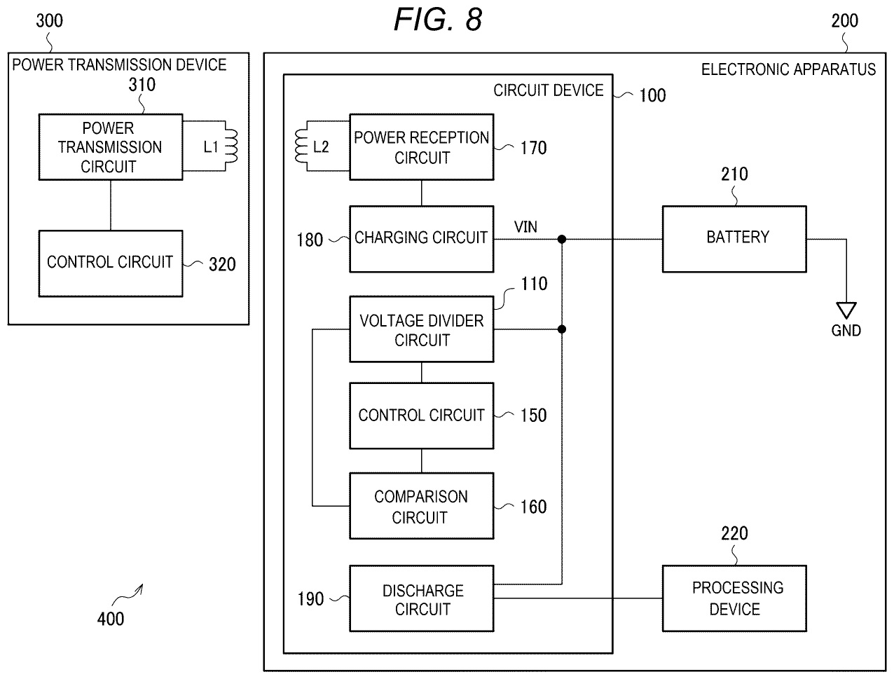

FIG. 8 shows a configuration example of an electronic apparatus 200 including the circuit device 100 and a system 400. The system 400 includes a power transmission device 300 and the electronic apparatus 200. Hereinafter, an example in which the power transmission device 300 transmits power to the electronic apparatus 200 by contactless power transmission will be described, but the power transmission may be a contact type.

The power transmission device 300 includes a power transmission coil L1, a power transmission circuit 310, and a control circuit 320. The power transmission circuit 310 transmits power to the electronic apparatus 200 by driving the power transmission coil L1. The control circuit 320 controls power transmission by the power transmission circuit 310.

The electronic apparatus 200 includes the circuit device 100, a battery 210, and a processing device 220. The battery 210 is a secondary battery, for example, a lithium ion secondary battery, a nickel-hydrogen rechargeable battery, a nickel-cadmium rechargeable battery, or the like. Further, the battery 210 may be implemented by a super capacitor or the like. The processing device 220 is a device that controls the electronic apparatus 200, and is, for example, a processor such as a CPU or a microcomputer.

The circuit device 100 includes a power reception coil L2, a power reception circuit 170, a charging circuit 180, a voltage divider circuit 110, a control circuit 150, a comparison circuit 160, and a discharge circuit 190. The voltage divider circuit 110, the control circuit 150, and the comparison circuit 160 are as described in the first to third configuration examples, and here, the battery voltage of the battery 210 is the measurement target voltage VIN. The power reception circuit 170 receives the power transmitted from the power transmission coil L1 via the power reception coil L2. That is, the power reception circuit 170 rectifies the AC voltage generated in the power reception coil L2 by the transmitted power into a DC voltage. The charging circuit 180 charges the battery 210 with the power received by the power reception circuit 170. The discharge circuit 190 supplies power to the processing device 220 by the power from the battery 210. For example, the discharge circuit 190 is a DC-DC converter that converts the battery voltage into a power supply voltage of the processing device 220.

The electronic apparatus 200 is a hearable device such as a hearing aid or an earphone for audio listening, or a wearable device. The earphone is, for example, what is called a wireless earphone. Note that as the electronic apparatus 200, various apparatuses such as a head-mounted display, a portable communication terminal such as a smartphone or a mobile phone, a wristwatch, a biological information measurement apparatus, a shaver, an electric toothbrush, a wrist computer, a handy terminal, or an in-vehicle apparatus of an automobile can be assumed.

Although the present embodiment has been described in detail above, it will be easily understood by those skilled in the art that many modifications can be made without substantially departing from the novel matters and effects according to the present disclosure. Accordingly, all the modifications are within the scope of the present disclosure. For example, a term described at least once together with a different term having a broader meaning or the same meaning in the specification or the drawings can be replaced with the different term in any place in the specification or the drawings. All combinations of the present embodiment and the modifications are also within the scope of the present disclosure. The configurations, operations, and the like of the system, the electronic apparatus, the power transmission device, the circuit device, the voltage divider circuit, the control circuit, the comparison circuit, and the like are not limited to those described in the present embodiment, and various modifications can be made.

What is claimed is:

1. A circuit device comprising:
a voltage divider circuit that is provided between a measurement target voltage node and a ground node, divides and outputs a measurement target voltage that is a voltage of the measurement target voltage node to a voltage division node;
a comparison circuit that compares a voltage of the voltage division node with a reference voltage; and
a control circuit, wherein
the voltage divider circuit includes a first resistor to an n-th resistor provided in series between the measurement target voltage node and the voltage division node, n being an integer of 3 or more, and a first transistor to an n-th transistor that are controlled to be turned on or off by control data from the control circuit with an i-th transistor coupled in parallel to an i-th resistor of the first resistor to the n-th resistor, i being an integer from 1 to n,
the control circuit sets a j-th transistor to one of on and off and sets the first transistor to the (j−1)-th transistor to the other of on and off, determines the control data by determining the j-th transistor is on or off based on a comparison result of the comparison circuit, j being an integer from 2 to n, and outputs measurement data of the measurement target voltage based on the determined control data.

2. The circuit device according to claim 1, wherein
the control circuit sets the n-th transistor to one of on and off and sets the first transistor to the (n−1)-th transistor to the other of on and off, determines whether the n-th transistor is on or off based on the comparison result of the comparison circuit, sets the (n−1)-th transistor to one of on and off and sets the first transistor to the (n−2)-th transistor to the other of on and off, determines whether the (n−1)-th transistor is on or off based on the comparison result of the comparison circuit, . . . , sets the first transistor to one of on and off, and determines whether the first transistor is on or off of based on the comparison result of the comparison circuit.

3. The circuit device according to claim 1, wherein
in the first resistor to the n-th resistor, a resistance value of the first resistor is minimum, a resistance value of the n-th resistor is maximum, and the resistance values are weighted in binary.

4. The circuit device according to claim 1, wherein
the voltage divider circuit includes a first resistance circuit provided between a first node and the voltage division node, and
the first resistor to the n-th resistor are coupled in series between the first node and the measurement target voltage node.

5. The circuit device according to claim 4, wherein
a resistance value of the first resistance circuit is larger than a total resistance value of the first resistor to the n-th resistor.

6. The circuit device according to claim 4, wherein
the voltage divider circuit includes a second resistance circuit provided between the voltage division node and the ground node.

7. The circuit device according to claim 1, wherein
the voltage divider circuit includes a first charge absorption transistor that is coupled to a source of the i-th transistor and has a gate to which an inverted signal of an i-th bit of the control data is input, and a second charge absorption transistor that is coupled to a drain of the i-th transistor and has a gate to which the inverted signal of the i-th bit is input.

8. The circuit device according to claim 7, wherein
a gate area of the first charge absorption transistor and the second charge absorption transistor is half a gate area of the i-th transistor.

9. The circuit device according to claim 1, wherein
the voltage divider circuit includes a first trimming resistor provided between a first node and the voltage division node, and a second trimming resistor provided between the voltage division node and the ground node,
the first resistor to the n-th resistor are coupled in series between the measurement target voltage node and the first node, and
variation adjustment of the reference voltage is performed by a resistance ratio between the first trimming resistor and the second trimming resistor.

10. The circuit device according to claim 9, wherein
a total resistance value of the first trimming resistor and the second trimming resistor is constant regardless of the resistance ratio.

11. The circuit device according to claim 1, wherein
the measurement of the measurement target voltage is intermittently performed.

12. An electronic apparatus comprising:
the circuit device according to claim 1; and
a battery, wherein
the measurement target voltage is a battery voltage of the battery.
